(19) United States
(12) Patent Application Publication
(10) Pub. No.: US 2026/0157161 A1
(43) Pub. Date: Jun. 4, 2026

(54) FUNCTIONAL CIRCUIT REGION INCLUDING FEEDTHROUGH VIA ARRANGEMENT, METHOD OF MANUFACTURING SAME AND SYSTEM FOR MANUFACTURING SAME

(71) Applicant: TAIWAN SEMICONDUCTOR MANUFACTURING COMPANY, LTD., Hsinchu (TW)

(72) Inventors: Cheng-Hua LIU, Hsinchu (TW); Kuang-Hung CHANG, Hsinchu (TW); Guan-Ming HUANG, Hsinchu (TW); Hsieh-Ting-Yang CHENG, Hsinchu (TW); Yuan-Te HOU, Hsinchu (TW)

(21) Appl. No.: 18/966,664

(22) Filed: Dec. 3, 2024

(51) Int. Cl. H01L 23/48; H01L 21/768; H01L 23/528

(52) U.S. Cl. CPC H10W 20/20; H10W 20/01; H10W 20/43

(57) ABSTRACT

A cell region includes: a transistor-components layer including a first feedthrough via arrangement (FTA); a first metallization layer over the transistor-components layer and including first-front-side segments, the first front-side segments including first and second front-side power grid (FPG) segments, and one or more front-side routing (FRTE) segments including a first FRTE segment; and a first buried metallization layer under the transistor-components layer and including first back-side segments, the first back-side segments including first and second back-side power grid (BPG) segments, and one or more back-side routing (BRTE) segments including a first BRTE segment. The first FTA couples the first FRTE segment to the first BRTE segment. Relative to the first direction and a second direction perpendicular to the first direction, the first BPG segment having a first notch partially occupied by at least a first portion of the first BRTE segment.

### BACKGROUND

The semiconductor integrated circuit (IC) industry produces a wide variety of analog and digital devices to address issues in a number of different areas. Developments in semiconductor process technology nodes have progressively reduced component sizes and tightened spacing resulting in progressively increased transistor density. ICs have become smaller.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is a block diagram, in accordance with some embodiments.

FIGS. 2A-2I are corresponding layout diagrams, in accordance with some embodiments.

FIGS. 3A-3E are corresponding layout diagrams, in accordance with some embodiments.

FIGS. 4A-4C are corresponding layout diagrams, in accordance with some embodiments.

FIGS. 5A-5B are corresponding cross-sections, in accordance with some embodiments.

FIGS. 6A-6D are corresponding block diagrams, in accordance with some embodiments.

FIG. 6E is a tree diagram, in accordance with some embodiments.

FIGS. 7A-7B are flowcharts of corresponding methods, in accordance with some embodiments.

FIG. 8 is a block diagram of an electronic design automation (EDA) system in accordance with some embodiments.

FIG. 9 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

In some embodiments, a cell region includes: a transistor-components layer including a first feedthrough via arrangement (FTA); a first metallization layer over the transistor-components layer and including first-front-side segments extending in a first direction (e.g., parallel to the X-axis), the first front-side segments including first and second front-side power grid (FPG) segments, and one or more front-side routing (FRTE) segments including a first FRTE segment; and a first buried metallization layer under the transistor-components layer and including first back-side segments extending in the first direction, the first back-side segments including first and second back-side power grid (BPG) segments, and one or more back-side routing (BRTE) segments including a first BRTE segment. The first FTA couples the first FRTE segment to the first BRTE segment. Relative to the first direction and a second direction perpendicular to the first direction, the first BPG segment having a first notch partially occupied by at least a first portion of the first BRTE segment. In some embodiments, the cell region is a referred to as a functional circuit cell region (FNCR). In some embodiments, the FTA is included in a feedthrough via cell region (FTCR) such that the FTCR is described as being embedded in the FNCR.

According to another approach, a counterpart to the FNCR 204 does not include routing segments in any metallization layer on the back-side. Rather, the other approach's (OO's) counterpart to the FNCR uses back-side metallization layers only for the power grid. In terms of signal routing, the OO's counterpart to the FNCR suffers congestion in the front-side metallization layers. By contrast, according to some embodiments, embedding the FTCR in the FNCR facilitates using back-side metallization layers for signal routing as well as for the power grid, which reduces signal-routing congestion on the front-side as compared to the other approach.

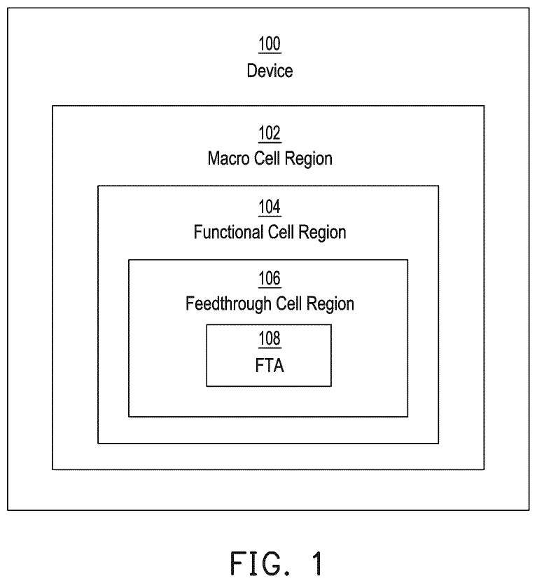

FIG. 1 is a block diagram of a device 100, in accordance with some embodiments.

Device 100 is an example of an integrated circuit (IC). In some embodiments, device 100 is referred to as a semiconductor device. Device 100 includes a macro region 102. In some embodiments, macro region 102 is comprised of one or more functional regions, e.g., circuit regions, or the like. In some embodiments, macro region 102 includes one or more of a memory, a power grid, a cell or cells, an inverter, a latch, a buffer, a driver, analog devices such as a digital-to-analog converter (DAC) or an analog-to-digital converter (ADC) or the like, clock trees, phase locked loops (PLLs), interfaces and/or any other type of circuit arrangement. Example memories include a static random access memory (SRAM), a dynamic RAM (DRAM), a resistive RAM, a magnetoresistive RAM (MRAM), a read only memory (ROM), or the like.

Macro region 102 is representable digitally in a library of standard cells. In some embodiments, macro region 102 is understood in the context of an analogy to the architectural hierarchy of modular programming, in which subroutines/procedures are called by a main program (or by other subroutines) to carry out a given computational function. In this context, device 100 uses macro region 102 to perform one or more given functions. Accordingly, in this context and in terms of architectural hierarchy, device 100 is analogous to the main program and macro region 102 is analogous to subroutines/procedures. In some embodiments, macro region 102 is a soft macro. In some embodiments, macro region 102 is a hard macro. In some embodiments, macro region 102 is a soft macro which is described digitally in register-transfer level (RTL) code. In some embodiments, synthesis, placement, and routing have yet to have been performed on macro region 102 such that the soft macro can be synthesized, placed, and routed for a variety of process technology nodes. In some embodiments, macro region 102 is a hard macro which is described digitally in a binary file format (e.g., Graphic Database System II (GDSII) stream format), where the binary file format represents planar geometric shapes, text labels, other information, and the like of one or more layouts of macro region 102 in hierarchical form. In some embodiments, a binary file format is referred to as a non-text file format. In some embodiments, synthesis, placement, and routing have been performed on macro region 102 such that the hard macro is specific to a particular process technology node.

In FIG. 1, macro region 102 includes a functional circuit region 104. Functional circuit region 104 includes at least one active device such as a transistor or the like. In some embodiments, functional circuit region 104 includes one or more logic gates. In some embodiments, functional circuit region 104 is or includes a buffer, a driver, an inverter, or the like. Examples of logic gates/circuits include circuits configured to perform logic functions AND, OR, NAND, NOR, XOR, INV, AND-OR-Invert (AOI), OR-AND-Invert (OAI), or the like. Examples of other functional circuits include a multiplexer (MUX), flip-flop, buffer (BUFF), driver (DRV), latch, delay, clock, memory, or the like.

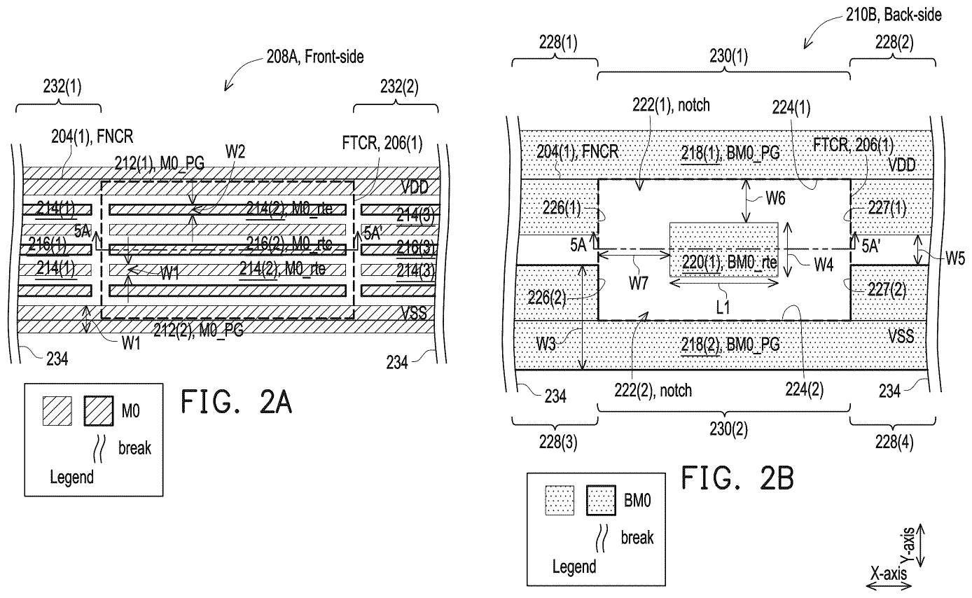

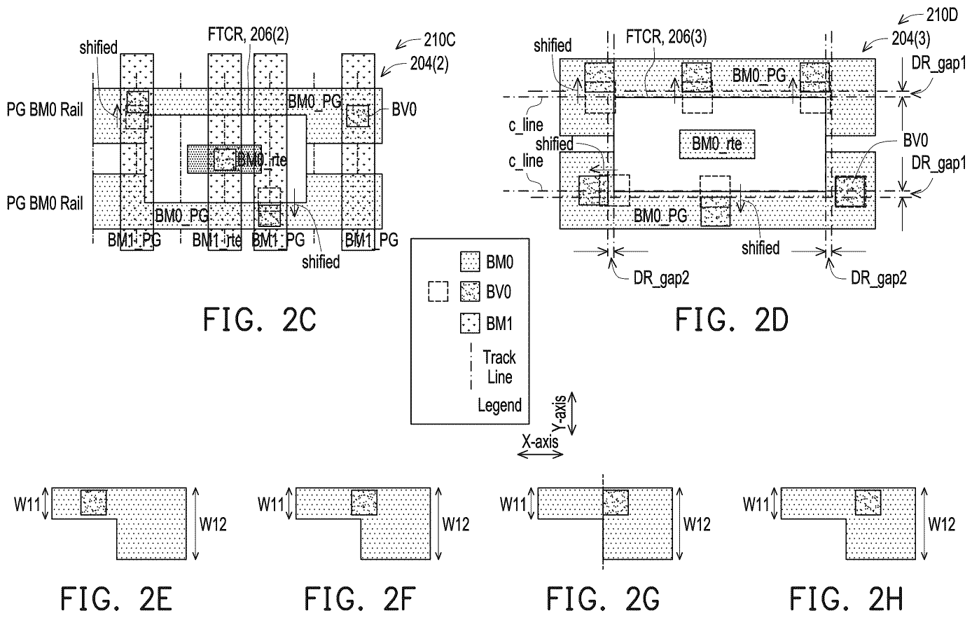

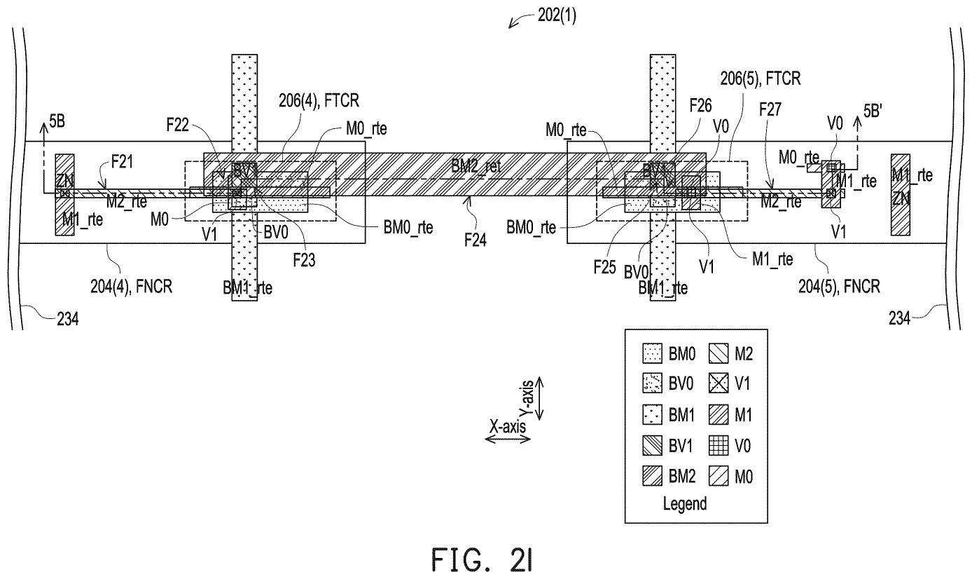

Functional circuit region 104 includes a feedthrough cell region 106 (see, e.g., FIGS. 2A-2D, 3A-3E, 4A-4C). In some embodiments, functional circuit region 104 is described as overlapping feedthrough cell region 106. In some embodiments, feedthrough cell region 106 is described as being embedded in functional circuit region 104.

Each of functional circuit region 104 and feedthrough cell region 106 includes corresponding segments in one or more metallization layers. In some embodiments, long and short axes of the segments extend correspondingly in perpendicular first and second directions (e.g., parallel to the X-axis and the Y-axis) in even ones of the metallization layers; in such embodiments, long and short axes of the segments extend correspondingly in the second and first directions (e.g., parallel to the Y-axis and the X-axis) in odd ones of the metallization layers. In such embodiments, boundaries of overlapping functional circuit region 104 and feedthrough cell region 106 are described in terms of the first and second directions such that the boundaries of feedthrough cell region 106 are within the boundaries of functional circuit region 104 relative to the first and second directions.

Regarding FIG. 1, in some embodiments, feedthrough cell region 106 is a separate cell in the library of standard cells. In some embodiments, feedthrough cell region 106 does not include an active device such as a transistor or the like. In some embodiments, feedthrough cell region 106 does not include a functional circuit element such as a buffer, driver, inverter, or the like. In some embodiments, feedthrough cell region 106 does not include a logic gate.

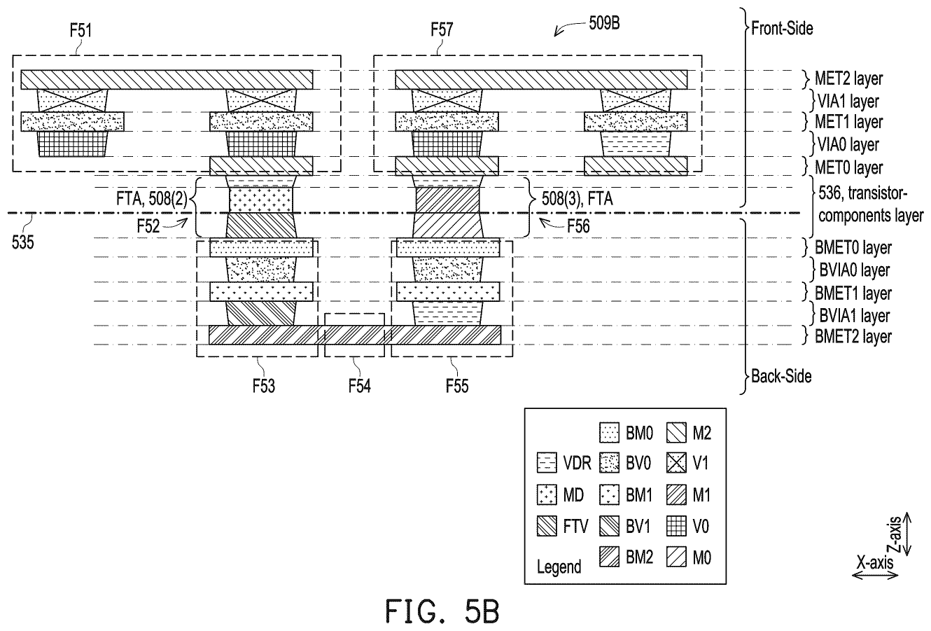

In some embodiments, functional circuit region 104 corresponds to a transistor-components layer (see, e.g., FIG. 5A) having circuitry components, e.g., transistor, formed thereon in a front-end-of-line (FEOL) fabrication. In functional circuit region 104, above and/or below the AR layer, various metal layers (see, e.g., FIGS. 5A-5B) interleaved with corresponding interconnection layers are stacked over and/or under insulating layers in a back end of line (BEOL) fabrication. The BEOL fabrication provides a power network and/or routing for circuitry of device 100, including macro region 102 and functional circuit region 104.

In some embodiments, functional circuit region 104 includes one or more active devices, passive devices, or the like. Examples of active devices or active elements include, but are not limited to, transistors, diodes, or the like. Examples of passive elements include, but are not limited to, capacitors, inductors, fuses, resistors, or the like.

In FIG. 1, feedthrough cell region 106 includes a feed-through via arrangement (FTA) 108 (see, e.g., FIG. 5A). FTA 108 is an arrangement that includes a feedthrough via (FTV) (see, e.g., FIG. 5A). FTA 108 extends through the transistor-components layer (see, e.g., 536 FIG. 5A) and electrically couples a segment in a metallization layer on a front-side of the transistor-components layer (e.g., the first metallization layer) and a segment in a backs-side metallization layer on a back-side of the transistor-components layer (e.g., the first back-side metallization layer), the back-side of the transistor-components layer being opposite to the front-side of the transistor-components layer.

FIGS. 2A-2B are corresponding front-side 208A and back-side 210B layout diagrams of a functional circuit region 204(1), in accordance with some embodiments.

Functional circuit region (FNCR) 204(1) is an example of a first functional cell region, e.g., functional cell region 104 of FIG. 1. In some embodiments, FNCR 204(1) comprises a first macro cell region, where the first macro cell region comprises a first device. In some embodiments, the first macro cell region and the first device are corresponding examples of macro cell region 102 and device 100 of FIG. 1. FNCR 204(1) includes a feedthrough cell region (FTCR) 206(1). FNCR 204(1) is an example of a first feedthrough cell region, e.g., FTCR 106 of FIG. 1. In some embodiments, FTCR 206(1) is described as being embedded in FNCR 204(1). For simplicity of illustration in each of FIGS. 2A-2B, relative to the X-axis, FNCR 204(1) and some of the structures therein correspondingly are truncated by break lines 234.

By being representative of FNCR 204(1), front-side 208A and back-side 210B layout diagrams correspondingly of FIGS. 2A-2B are representative of a transistor-based device. Structures in the device are represented by patterns (also known as shapes) in the layout diagram. For simplicity of discussion, elements in front-side 208A layout diagram and back-side 210B layout diagram correspondingly of FIGS. 2A-2B (and also in other layout diagrams disclosed herein) will be referred to as if they are structures rather than patterns. For example, instances of element 214 in FIG. 2A represent instances of a routing segment in a first metallization layer. In the following discussion, instances of element 214 are referred to as instances of routing segment 214 rather than as instances of routing pattern 214. In each of FIGS. 2A-2B, section line 5A-5A′ extends parallel to the X-axis. In some embodiments, section line 5A-5A′ of FIGS. 2A-2B corresponds to cross-section 509A of FIG. 5A.

In FIGS. 2A-2B, as well as in other layout diagrams disclosed herein, an orthogonal Cartesian coordinate system is assumed in which first, second and third directions are, e.g., correspondingly parallel to the X-axis, the Y-axis and the Z-axis. A layout diagram is a top view. Shapes in the layout diagram are two-dimensional relative to, e.g., the X-axis and the Y-axis, whereas the device being represented is three-dimensional. As such, a shape in such layout diagrams is described as having a width/length relative to the X-axis and a height relative to the Y-axis. Relative to the Z-axis, e.g., a bottom/back side of a first component being represented in the layout diagram is stacked on a top/front side of a second component device being represented in the layout diagram, or a top/front back side of the first component is stacked, e.g., under a bottom/back side of the second component. In some embodiments, the first to third directions correspond to directions other than the X-axis, Y-axis and Z-axis.

Typically, relative to the Z-axis, the device is organized as a stack of layers in which are located corresponding structures, i.e., to which belong corresponding structures. Each shape in the layout diagram represents, more particularly, a component in a corresponding layer of the corresponding device. Also, typically, the layout diagram represents relative depth, i.e., positions along the Z-axis, of shapes and corresponding layers by superimposing a second shape on a first shape so that the second shape at least partially overlaps the first shape. For simplicity of illustration, some structures which have a first order of stacking along the Z-axis in the device are represented in the layout diagram using a second order of stacking along the Z-axis, i.e., a different/distorted stacking order; for example, see FIG. 2I.

Layout diagrams vary in terms of the amount of detail represented. In some circumstances, selected layers of a layout diagram are combined/abstracted into a single layer, e.g., for purposes of simplification. Alternatively, and/or additionally, in some circumstances, not all layers of the corresponding device are represented, i.e., selected layers of the layout diagram are omitted, e.g., for simplicity of illustration. Alternatively, and/or additionally, in some circumstances, not all elements of a given depicted layer of the corresponding device are represented, i.e., selected elements of the given depicted layer of the layout diagram are omitted, e.g., for simplicity of illustration. FIG. 2A and the other layout diagrams disclosed herein are examples of layout diagrams in which selected layers and/or selected elements of depicted given layers, have been omitted.

Front-side layout diagram 208A of FIG. 2A includes a first metallization layer on the transistor-components layer (see, e.g., 536 FIG. 5A). Back-side layout diagram 208B of FIG. 2B includes a first buried metallization layer under the transistor-components layer (see, e.g., 536 FIG. 5A). Each of the first metallization layer and the first buried metallization layer correspondingly includes segments which are electrically conductive. In some embodiments, depending upon the numbering convention of the corresponding process technology node by which such a device is fabricated, the first layer metallization is either metallization layer zero (MET0) or metallization layer one (MET1), and correspondingly a first interconnection layer on the first metallization layer is either interconnection layer zero (VIA0) or interconnection layer one (VIA1). In such embodiments, again depending upon the numbering convention of the corresponding process technology node, the first buried metallization layer is either buried metallization layer zero (BMET0) or buried metallization layer one (BMET1), and correspondingly a first buried interconnection layer under the first metallization layer is either interconnection layer zero (VIA0) or interconnection layer one (VIA1).

In FIG. 2A, and in the other figures disclosed herein, the following nomenclature is adopted: the first metallization layer is assumed to be MET0; the first interconnection layer is assumed to be VIA0; the second metallization layer is assumed to be MET1; the second interconnection layer is assumed to be VIA1; and the third metallization layer is assumed to MET2. Metallization segments in layer MET0 are referred to as M0 segments. Via structures in layer VIA0 are referred to as V0 structures. Metallization segments in layer MET1 are referred to as M1 segments. Via structures in layer VIA1 are referred to as V1 structures. Metallization segments in layer MET2 are referred to as M2 segments.

In FIG. 2B, and in the other figures disclosed herein, the following nomenclature is adopted: the first buried metallization layer is assumed to be BMET0; the first buried interconnection layer is assumed to be BVIA0; the second buried metallization layer is assumed to be BMET1; the second buried interconnection layer is assumed to be BVIA1; and the third buried metallization layer is assumed to BMET2. Metallization segments in layer BMET0 are referred to as buried M0 segments. Via structures in layer BVIA0 are referred to as BV0 structures. Metallization segments in layer BMET1 are referred to as BM1 segments. Via structures in layer BVIA1 are referred to as BV1 structures. Metallization segments in layer BMET2 are referred to as BM2 segments.

In FIGS. 2A-2B, and in some of the other figures disclosed herein, the layout diagrams assume that a dual Damascene type of photolithographic process will be used by the corresponding process technology node. Accordingly, In FIGS. 2A-2B, and in some of the other figures disclosed herein, relative to the Y-axis, alternating segments in a given metallization layer, e.g., metallization layer MET0 and buried metallization layer BMET0, are shown with different color border lines, different fill colors, different fill patterns, or the like. In some embodiments, the corresponding process technology node uses a photolithographic process other than the dual Damascene type of photolithographic process.

Returning to FIG. 2A, the M0 segments extend parallel to the X-axis. The M0 segments include: M0 power grid (PG) (M0_PG) segments 212(1) and 212(2); and instances of M0 routing (M0_rte) segments 214(1)-214(3); M0_rte segments 216(1)-216(3).

Relative to the Y-axis: a top boundary correspondingly of each of FNCR 204(1) and FTCR 206(1) aligns substantially with a centerline of M0_PG segment 212(1); a bottom boundary correspondingly of each of FNCR 204(1) and FTCR 206(1) aligns substantially with a centerline of M0_PG segment 212(2); corresponding instances of M0_rte segments 214(1), 214(2) and 214(3) are collinear; and M0_rte segments 216(1), 216(2) and 216(3) are collinear;

Relative to the X-axis: instances of M0_rte segment 214(2) are between corresponding instances of M0_rte segments 214(1) and 214(3); M0_rte segment 216(2) is between M0_rte segments 216(1) and 216(3); instances of M0_rte segment 214(2) are separated from corresponding instances of M0_rte segment 214(1) by a gap corresponding to a left boundary of FTCR 206(1); M0_rte segment 216(2) is separated from M0_rte segment 216(1) by a gap corresponding to the left boundary of FTCR 206(1); instances of M0_rte segment 214(2) are separated from corresponding instances of M0_rte segment 214(3) by a gap corresponding to a right boundary of FTCR 206(1); M0_rte segment 216(2) is separated from M0_rte segment 216(3) by a gap corresponding to the right boundary of FTCR 206(1); M0_rte segment 216(1) and instances of M0_rte segment 214(1) are located on a left side 232(1) of FTCR 206(1); and M0_rte segment 216(3) and instances of M0_rte segment 214(2) are located on a right side 232(1) of FTCR 206(1);

Relative to the Y-axis: each of M0_PG segments 212(1) and 212(2) has a width (size) W1; and each of M0_rte segments 216(1)-216(3) and each instance of M0_rte segments 214(1)-214(3) has a width W2. Width W2 is less than width W1 such that W2<W1. Widths W1 and W2 are determined according to the scale and corresponding ones of the design rules of the associated semiconductor process technology node.

Regarding FIG. 2A, sizes of gaps determined according to the scale and corresponding ones of the design rules of the associated semiconductor process technology node include the following: relative to the Y-axis, widths of gaps between M0_PG segments 212(1) and 212(2) and adjacent M0_rte segments; relative to the Y-axis, widths of the gaps between adjacent M0_rte segments; and relative to the X-axis, widths of the gaps that separate adjacent M0_rte segments.

In FIG. 2B, the BM0 segments extend parallel to the X-axis. The BM0 segments include: BM0 power grid (PG) (BM0_PG) segments 218(1) and 218(2); and a BM0 routing (BM0_rte) segment 220(1).

Relative to the Y-axis: the top boundary correspondingly of each of FNCR 204(1) and FTCR 206(1) aligns substantially with a centerline of BM0_PG segment 218(1); and the bottom boundary correspondingly of each of FNCR 204(1) and FTCR 206(1) aligns substantially with a centerline of BM0_PG segment 218(2).

BM0_PG segment 218(1) is formed with a notch 221(1). BM0_PG segment 218(2) is formed with a notch 221(2). Notch 221(1) has a bottom side 224(1), a left side 226(1) and a right side 227(1). Notch 221(2) has a bottom side 224(2), a left side 226(2) and a right side 227(2).

Relative to the Y-axis: the top boundary of FTCR 206(1) aligns substantially with bottom side 224(1) of notch 222(1); the bottom boundary of FTCR 206(1) aligns substantially with bottom side 224(2) of notch 222(2); each of BM0_PG segments 218(1) and 218(2) has a width (size) W3; and BM0_rte segment 220(1) has a width W4.

Relative to the X-axis: the left boundary of FTCR 206(1) aligns substantially with left side 226(1) of notch 222(1) and left side 226(2) of notch 222(2); and the right boundary of FTCR 206(1) aligns substantially with right side 227(1) of notch 222(1) and right side 227(2) of notch 222(2).

Relative to the X-axis: each of a section 228(1) of BM0_PG segment 218(1) and a section 228(3) of BM0_PG segment 218(2), each of which is correspondingly to the left of FTCR 206(1), has a width (size) W3; each of a section 228(2) of BM0_PG segment 218(1) and a section 228(4) of BM0_PG segment 218(2), each of which is correspondingly to the right of FTCR 206(1), has width W3; section 230(1) of BM0_PG 218(1), which is between sections 228(1) and 228(2), has a width of ≈(½*W3); section 230(2) of BM0_PG 218(2), which is between sections 228(3) and 228(4), has width ≈(½*W3); section 228(1) of BM0_PG 218(1) is separated from section 228(3) of BM0_PG 218(2) by a gap having a width W5; section 228(2) of BM0_PG 218(1) is separated from section 228(4) of BM0_PG 218(2) by a gap having width W5; section 230(1) of BM0_PG 218(1) is separated from BM0_rte 220(2) by a gap substantially having a width W6; and section 230(2) of BM0_PG 218(2) is separated from BM0_rte 220(2) by a gap substantially having width W6.

In some embodiments, sections 228(1)-228(2) of BM0_PG segment 218(1) and sections 228(3)-228(4) of BM0_PG segment 218(2) are referred to as half-width sections. In some embodiments, section 230(1) of BM0_PG segment 218(1) and section 230(2) of BM0_PG segment 218(2) are referred to as full-width sections.

In some embodiments, width W6 is approximately equal to, or less than, width W4 such that W6≈≤W4. Width W3 is also determined according to the scale and corresponding ones of the design rules of the associated semiconductor process technology node.

FIG. 2B assumes that width W4 is equal to or greater than a minimum width for a BM0_rte segment referred to as Wy_BM0_rte_min, the latter being relative to the Y-axis, where each of W4 and Wy_BM0_rte_min is determined according to the scale and corresponding ones of the design rules of the associated semiconductor process technology node. Width W4 is less than width W3 such that W4<W3. Also, width W1 is less than width W4 such that W1<W4.

FIG. 2B also assumes that width W4 is substantially equal to (½*W3) such that W4=(½*W3). In some embodiments, width W4 has value substantially different than (½*W3) albeit W4<W3. FIG. 2B assumes that width W5 is equal to or greater than a minimum height for a gap between adjacent BM0 segments referred to as H_BM0_gap, the latter being relative to the Y-axis, where each of W5 and H_BM0_gap is determined according to the scale and corresponding ones of the design rules of the associated semiconductor process technology node. In FIG. 2B, width W5 is less than width W4 such that W5<W4.

Relative to the X-axis, BM0_rte segment 220(1) has a length (size) L1. FIG. 2B assumes that length L1 is equal to or greater than a minimum length for a BM0_rte segment referred to as Lx_BM0_rte_min, the latter being relative to the X-axis, such that Lx_BM0_rte_min≤L1, where L_BM0_rte_min is determined according to the scale and corresponding ones of the design rules of the associated semiconductor process technology node.

In FIG. 2B, relative to the X-axis: BM0_rte segment 220(1) is separated from the left boundary of FTCR 206(1) by a gap having a size W7, i.e., BM0_rte segment 220(1) is separated from each of section 228(1) of BM0_PG segment 218(1) and section 228(3) of BM0_PG segment 218(2) by the gap substantially having size W7; and BM0_rte segment 220(1) is separated from the right boundary of FTCR 206(1) by a gap having size W7, i.e., BM0_rte segment 220(1) is separated from each of section 228(2) of BM0_PG segment 218(1) and section 228(4) of BM0_PG segment 218(2) by the gap substantially having size W7.

FIG. 2B assumes that length W7 is equal to or greater than a minimum length for a gap between BMO segments referred to as Wx_BM0_gap_min, the latter being relative to the X-axis, such that Wx_BM0_gap_min≤W7, where each of Wx_BM0_gap_min and W7 is determined according to the scale and corresponding ones of the design rules of the associated semiconductor process technology node.

Relative to the X-axis, FIG. 2B assumes that BM0_rte segment 220(1) is substantially centered between section 228(1) of BM0_PG segment 218(1) and section 228(2) of BM0_PG segment 218(1), and between section 228(3) of BM0_PG segment 218(2) and section 228(4) of BM0_PG segment 218(2). That is, relative to the X-axis, FIG. 2B assumes that BM0_rte segment 220(1) is substantially centered between the left and right boundaries of FTCR 206(1).

Relative to the X-axis, FTCR 206(1) has a width referred to as W_FTCR_206(1). In some embodiments in which width W_FTCR_206(1) is substantially greater than Lx_BM0_rte_min plus twice Wx_BM0_gap_min such that Lx_BM0_rte_min+2*Wx_BM0_gap_min<W_FTCR_206(1), BM0_rte segment 220(1) is not necessarily substantially centered between section 228(1) of BM0_PG segment 218(1) and section 228(2) of BM0_PG segment 218(1), and between section 228(3) of BMO_PG segment 218(2) and section 228(4) of BM0_PG segment 218(2). However, in such embodiments, relative to the X-axis:
BM0_rte segment 220(1) is separated from each of section 228(1) of BM0_PG segment 218(1) and section 228(3) of BM0_PG segment 218(2) by a first gap having at least a size equal to or greater than Wx_BM0_gap_min; and BM0_rte segment 220(1) is separated from each of section 228(2) of BM0_PG segment 218(1) and section 228(4) of BM0_PG segment 218(2) by a second gap having at least a size equal to or greater than Wx_BM0_gap_min.

Relative to the Y-axis, FIG. 2B assumes that BM0_rte segment 220(1) is substantially centered between section 230(1) of BM0_PG segment 218(1) and section 230(2) of BM0_PG segment 218(2).

That is, relative to the Y-axis, FIG. 2B assumes that BM0_rte segment 220(1) is substantially centered between the top and bottom boundaries of FTCR 206(1).

Relative to the Y-axis, FTCR 206(1) has a height referred to as H_FTCR_206(1). In some embodiments in which height H_FTCR_206(1) is substantially greater than Wy_BM0_rte_min plus twice H_BM0_min such that Wy_BM0_rte_min+2*H_BM0_gap<H_FTCR_206(1), BM0_rte segment 220(1) is not necessarily substantially centered between section 230(1) of BM0_PG segment 218(1) and section 230(2) of BM0_PG segment 218(2). However, in such embodiments, relative to the X-axis: BM0_rte segment 220(1) is separated from each of section 230(1) of BM0_PG segment 218(1) and section 230(2) of BM0_PG segment 218(2) by a gap having at least a size equal to or greater than H_BM0_min.

According to another approach, a counterpart to FNCR 204(1) does not include routing segments in any metallization layer on the back-side, i.e., no routing segments in metallization layer BMET0 nor in any metallization therebelow. Rather, the other approach's (OO's) counterpart to FNCR 204(1) uses back-side metallization layers only for the power grid. In terms of signal routing, the OO's counterpart to FNCR 204(1) suffers congestion in the front-side metallization layers. By contrast, according to some embodiments, embedding a feedthrough cell region (e.g., FTCR 206(1) in a functional circuit region (e.g., FNCR 204(1)) facilitates using back-side metallization layers for signal routing as well as for the power grid, which reduces signal-routing congestion on the front-side as compared to the other approach.

Recalling that section line 5A-5A′ in each of FIGS. 2A-2B corresponds to the cross-section of FIG. 5A, the discussion will turn to FIG. 5A and then revert to FIGS. 2A-2B.

FIG. 5A is a cross-section 509A of a device, in accordance with some embodiments.

More particularly, cross-section 509A is a cross-section of a second FTCR in a second FNCR, where the second FNCR comprise a second macro cell region, and where the second macro cell region comprises a second device. In some embodiments, the second FTCR is an example of FTCR 206(1) of FIGS. 2A-2B, the second FNCR is an example of FNCR 204(1) of FIGS. 2A-2B, and the second macro cell region and the second device are corresponding examples of macro cell region 102 and device 100 of FIG. 1. That is, in some embodiments, cross-section 509A corresponds to section line 5A-5A′ of FIGS. 2A-2B.

In FIG. 5A, a front-side and a back-side of cross-section 509A is determined relative to a reference line 536. A transistor layer 546(1) extends from the front-side across reference line 546(1) into the back-side of cross-section 509.

Cross-section 509A includes: in the BMET0 layer, a BM0_rte 520(1) which is an example of BM0_rte segment 220(1) of FIG. 2B; in transistor-components 536, a feedthrough arrangement (FTA) 508(1) on BM0_rte segment 520(1); and in the MET0 layer, an M0_rte segment 516(2) which is on FTA 508(1) and which is an example of M0_rte segment 216(2) of FIG. 2B.

FTA 508(1) includes: a feedthrough via (FTV) 546(1) on BM0_rte segment 520(1); a metal-to-source/drain (MD) contact 544(1) on FTV 546(1); a via-to-MD (VD) contact on MD contact 544(1) and under M0_rte segment 516(2). MD contact 544(1), VDR 542(1) and M0_rte segment 516(2) are on the front-side of cross-section 509. FTV 546(1) and BM0_rte segment 520(1) are on the back-side of cross-section 509.

An active region (AR) layer 548 is included in transistor-components layer 536 below reference line 536. Active regions (not shown) are formed in AR layer 548. FTV 546(1) extends through, and downward beyond, AR layer 548.

Discussion will now return to FIGS. 2A-2B.

For simplicity of illustration, FIGS. 2A-2B omit structures in the transistor-components layer (see, e.g., 536 FIG. 5A). Nevertheless, FIGS. 2A-2B assume that an FTA (e.g., FTA 508(1) FIG. 5A) is coupled between M0_rte segment 216(2) of FIG. 2A and BM0_rte segment 220(1) of FIG. 2B.

FIG. 2C is a back-side layout diagram 210C of a FNCR 204(2), in accordance with some embodiments.

Back-side layout diagram 210C of FIG. 2C is similar to back-side layout diagram 210B of FIG. 2B. For brevity, the discussion will focus on differences of back-side layout diagram 210C as compared to back-side layout diagram 210B rather than on similarities.

Back-side layout diagram 210C of FIG. 2C includes: FNCR 204(2); FTCR 206(2); BM0_PG segments and a BM0_rte segment in buried metallization layer BET0; buried via (BV0) structures in buried interconnection layer BVIA0; BM1_PG segments and a BM1_rte segment in buried metallization layer BMET1; and track lines extending parallel to the Y-axis.

The BM0_PG segments are configured with notches. Portions of the BM0_rte segment are correspondingly in the notices of the BM0_PG segments. In FIG. 2C, the BM1_PG segments, the BM1_rte segment and the BV0 structures are aligned to corresponding ones of the track lines.

To ensure compliance with design rules of the associated semiconductor process technology node, locations of two selected ones of the BV0 structures are shifted relative to the Y-axis. For example, the two selected BV0 structures are shifted to improve overlap between the BV0 structures and corresponding portions of the BM0 segments.

FIG. 2D is a back-side layout diagram 210D of a FNCR 204(3), in accordance with some embodiments.

Back-side layout diagram 210D of FIG. 2D is similar to back-side layout diagram 210C of FIG. 2C. For brevity, the discussion will focus on differences of back-side layout diagram 210D as compared to back-side layout diagram 210C rather than on similarities. For example, layout diagram 210D does not include BM1 segments nor track lines.

Relative to the Y-axis: a top boundary of FTCR 206(3) aligns substantially with a corresponding centerline c_line of the upper M0_PG segment; and a bottom boundary of FTCR 206(3) aligns substantially with a corresponding centerline c_line of the lower M0_PG segment.

In FIG. 2D, to ensure compliance with design rules of the associated semiconductor process technology node, locations of four selected ones of the BV0 structures are shifted relative to the Y-axis. For example, first, second and third ones of the four selected BV0 structures are shifted parallel to the Y-axis to improve overlap between the BV0 structures and corresponding portions of the BM0_PG segments and to ensure that the first, second and third shifted BV0 structures are located a minimum offset DR_gap1 from the edge of the corresponding portions of the BM0_PG segments. For example, a fourth one of the four selected BV0 structures is shifted parallel to the X-axis to improve overlap between the BV0 structure and the corresponding portion of the BM0_PG segment and to ensure that the fourth shifted BV0 structure is located a minimum offset DR_gap2 from the edge of the corresponding portions of the BM0_PG segments. In some embodiments, one or more of the BV0 structures is shifted relative to each of the X-axis and the Y-axis.

FIGS. 2E-2H are corresponding back-side layout diagrams, in accordance with some embodiments.

The back-side layout diagrams of FIGS. 2E-2H are similar to an excerpted portion of back-side layout diagram 210D of FIG. 2D. For brevity, the discussion will focus on differences of the back-side layout diagrams of FIGS. 2E-2E as compared to back-side layout diagrams 210D of FIG. 2D rather than on similarities.

In FIGS. 2E-2H, relative to the Y-axis, a narrower portion of the BM0 segment has a width W11 and a wider portion of the BM0 segment has a width W12, where W11 <W12. FIGS. 2E-2H show different starting positions of a BV0 structure with respect to the BM0 segment. It is assumed that the layout diagrams of FIGS. 2E-2H will be checked for compliance with design rules including the design rules involving DR_gap1 of FIG. 2D and DR_gap2E, and will be adjusted accordingly if merited.

FIG. 2I is layout diagram of a macro cell region 202(1), in accordance with some embodiments.

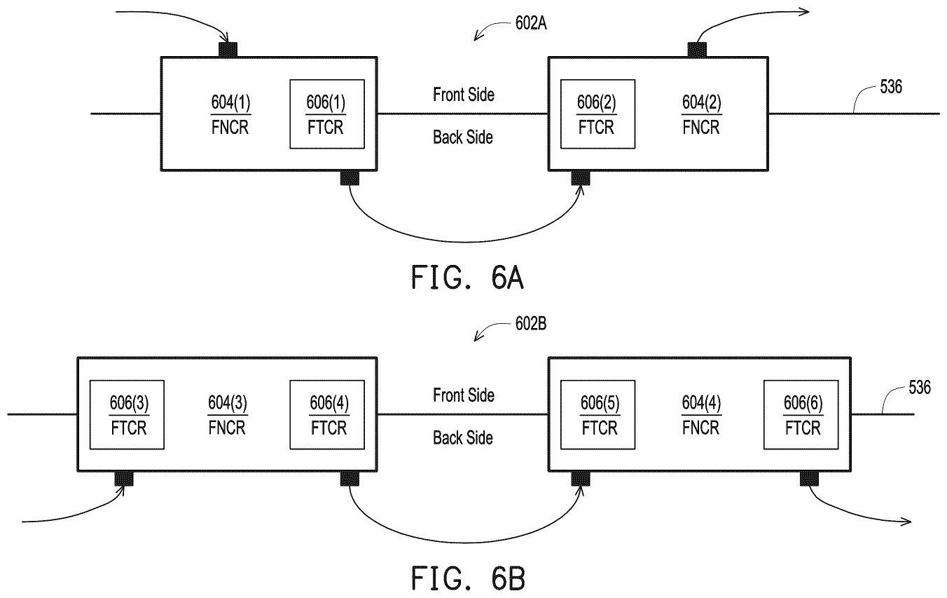

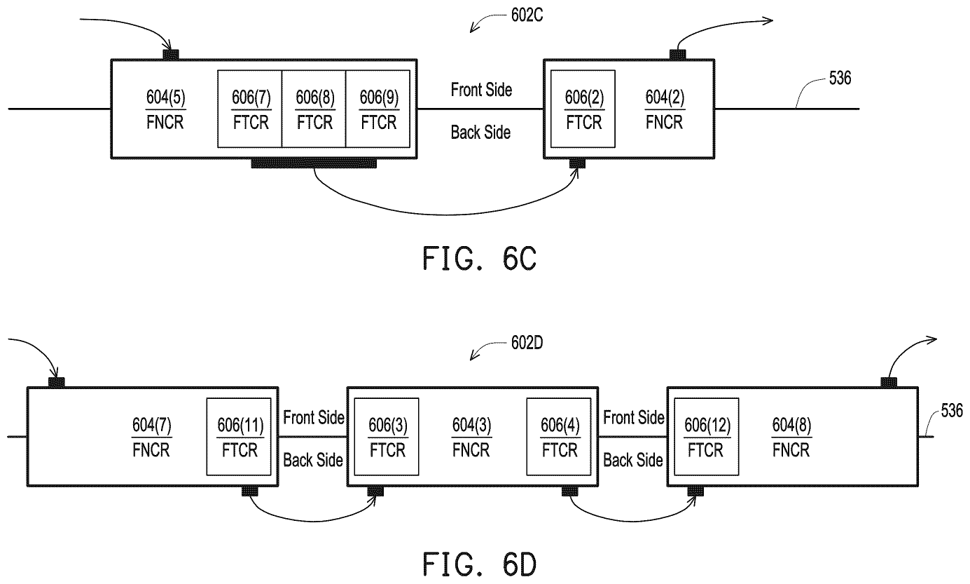

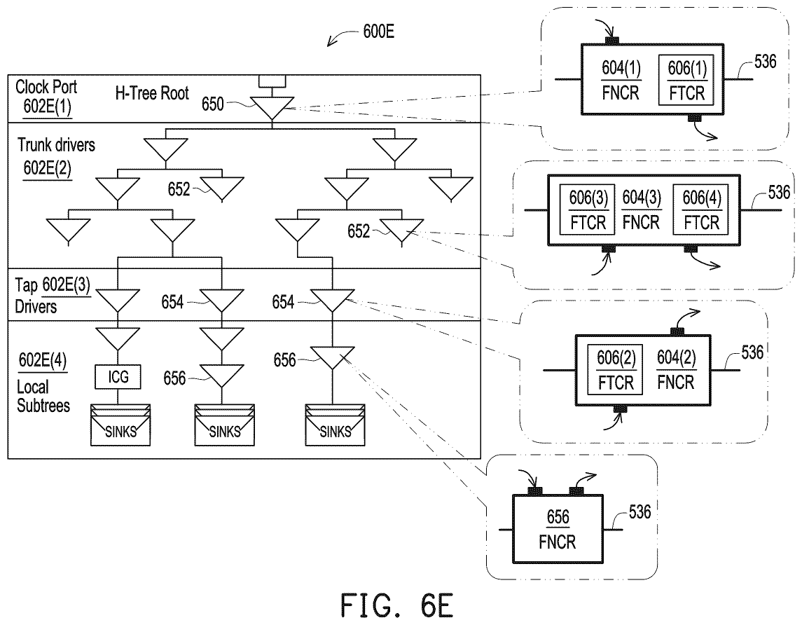

Macro cell region 202(1) comprises an associated device. In some embodiments, macro cell region 202(1) and the associated device are corresponding examples of macro cell region 102 and device 100 of FIG. 1. In some embodiments, macro cell region 202(1) is an example of the macro cell region of FIG. 6A.

Regarding FIG. 2I, for simplicity of illustration, some structures which have a first order of stacking along the Z-axis in the associated device are represented in the layout diagram FIG. 2I using a second order of stacking along the Z-axis, i.e., a different/distorted stacking order.

FIG. 2I includes an offset section line 5B-5B′, portions of which extend parallel to the X-axis and portions of which extend parallel to the Y-axis. In some embodiments, section line 5B-5B′ of FIG. 2I corresponds to the cross-section of FIG. 5B.

Macro cell region 202(1) includes FNCR 204(4) and FNCR 204(5). FNCR 204(4) includes FTCR 204(4). FNCR 204(5) includes FTCR 204(5).

For simplicity of illustration, FIG. 2I omits structures in the transistor-components layer (see, e.g., 536 FIG. 5B). Nevertheless, FIG. 2I assumes that first and second FTAs (e.g., FTAs 508(2) and 508(3) of FIG. 5B) coupled between corresponding pairs of an M0_rte segment and a BM0_rte segment in FTCR 206(4) and FTCR 206(5).

Offset section line 5B-5B′ represents a signal path comprised of the following fragments: a first fragment F21 on the front-side and above the transistor-components layer that includes structures of FNCR 204(4) that are in the layers MET2, VIA1, MET1, VIA0 and MET0; a second fragment F22 in the transistor-components layer that includes the first FTA of FNCR 204(4) that is in the transistor-components layer; a third fragment F23 on the back-side and below the transistor-components layer that includes structures of FNCR 204(4) that are in the layers BMET0, BVIA0, BMET1, BVIA1 and BMET2; a fourth fragment F24 on the back-side and below the transistor-components layer that a portion of a BM2_ret segment in the BMET2 layer that is between FNCR 204(4) and FNCR 204(5); a fifth fragment F25 on the back-side and below the transistor-components layer that includes structures of FNCR 204(5) that are in the layers BMET0, BVIA0, BMET1, BVIA1 and BMET2; a sixth fragment F26 on the front-side and above the transistor-components layer that includes the second FTA of FNCR 204(5) that is in the transistor-components layer; and a seventh fragment F27 on the front-side and above the transistor-components layer that includes structures of FNCR 204(5) that are in the layers MET2, VIA1, MET1, VIA0 and MET0.

The discussion will now resume progressing through the figures in alphanumerical order.

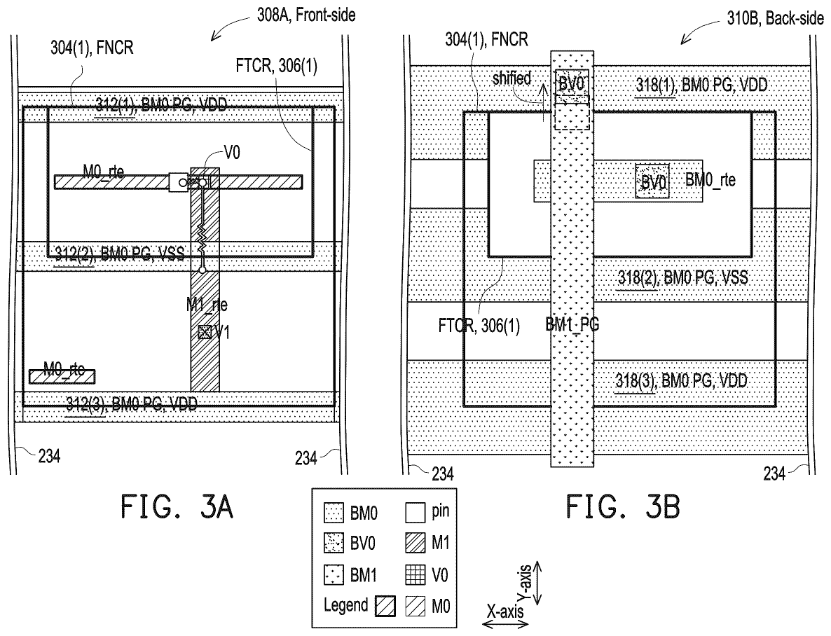

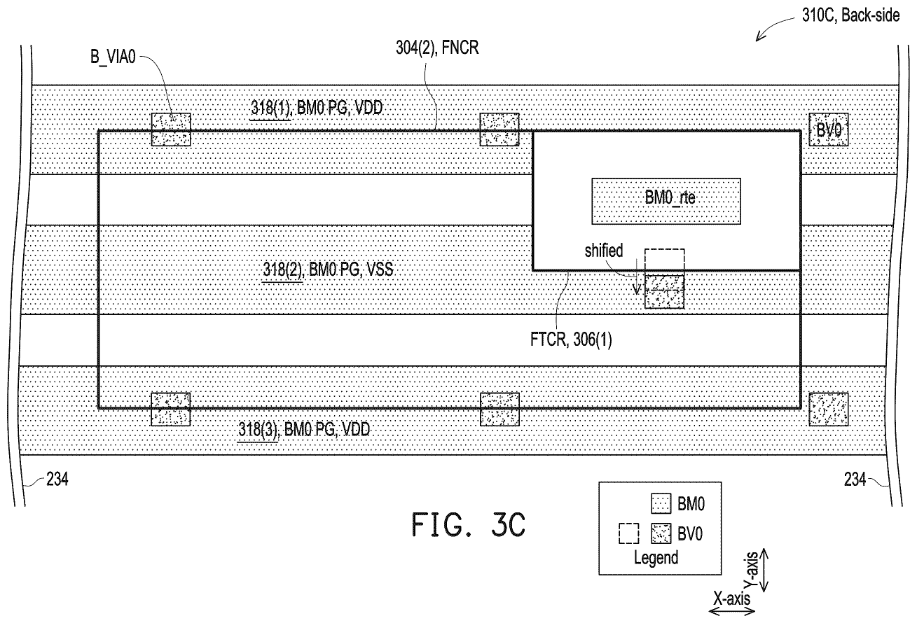

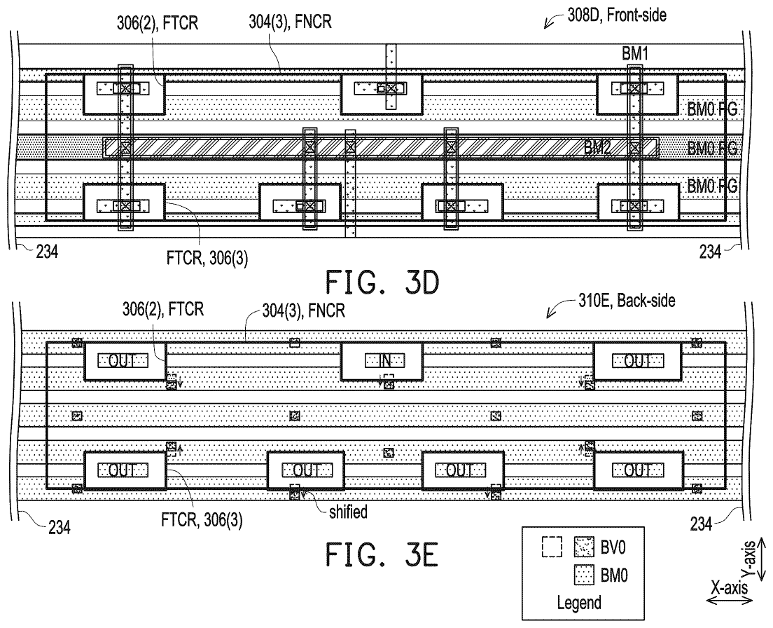

FIGS. 3A-3B are corresponding front-side 308A and back-side 310B layout diagrams of a functional circuit region 304(1), in accordance with some embodiments.

Front-side 308A and back-side 310B layout diagrams are similar correspondingly to front-side 208A and back-side 210B layout diagrams of FIGS. 2A-2B. For brevity, the discussion will focus on differences of front-side 308A and back-side 310B layout diagrams as compared to front-side 208A and back-side 210B layout diagrams of FIGS. 2A-2B rather than on similarities.

Relative to the Y-axis: a top boundary correspondingly of each of FNCR 304(1) and FTCR 306(1) aligns substantially with centerlines of M0_PG segment 312(1) and notched BM0_PG segment 318(1); a bottom boundary of FTCR 306(1) aligns substantially with centerlines of M0_PG segment 312(2) and notched BM0_PG segment 318(2); and a bottom boundary of FNCR 304(1) aligns substantially with centerlines of M0_PG segment 312(2) and un-notched BM0_PG segment 318(3).

In FIG. 3B, to ensure compliance with design rules of the associated semiconductor process technology node, a location of a selected one of the BV0 structures is shifted relative to the Y-axis. For example, the selected BV0 structure is shifted to improve overlap between the BV0 structure and the corresponding portion of BM0 segment 318(1).

In FIG. 3B, FNCR 304(1) is an example of a BUFFD4 cell region. In some embodiments, BUFFDx is an alphanumeric text string used as an adjective that is intended to connote that the corresponding cell region is a buffer cell region. for which the driving strength of the cell region is DX, where X is a multiple of a unit driving strength D. FNCR 304(1) has x=4 such that the driving strength is D4.

FIG. 3C is back-side layout diagram 310C of an FNCR 304(2), in accordance with some embodiments.

Back-side layout diagram 310C is similar to back-side layout diagram 310B of FIG. 3B. For brevity, the discussion will focus on differences of back-side layout diagram 310C as compared to back-side layout diagram 310B of FIG. 3B rather than on similarities. FNCR 304(2) is an expanded version of FNCR 304(1) of FIG. 3B.

In FIG. 3C, to ensure compliance with design rules of the associated semiconductor process technology node, a location of a selected one of the BV0 structures is shifted relative to the Y-axis. For example, the selected BV0 structure is shifted to improve overlap between the BV0 structure and the corresponding portion of BM0 segment 318(2). In FIG. 3C, FNCR 304(2) is an example of a level shifter cell region.

FIGS. 3D-3E are corresponding front-side 308D and back-side 310E layout diagrams of an FNCR 304(3), in accordance with some embodiments.

Back-side layout diagram 310E is similar back-side layout diagram 310B of FIG. 3B. For brevity, the discussion will focus on differences of back-side layout diagram 310E as compared to back-side layout diagram 310B of FIG. 2B rather than on similarities. Layout diagram 310E is an expanded version of layout diagram 310B of FIG. 3B.

In FIG. 3E, to ensure compliance with design rules of the associated semiconductor process technology node, a location of selected ones of the BV0 structures are shifted relative to the Y-axis. For example, the selected BV0 structures are shifted to improve overlap between the BV0 structures and the corresponding portions of the BM0 segments.

In FIGS. 3D-3E, FNCR 304(3) is an example of a CK_BUFFD32 cell region. In some embodiments, CK_BUFFDx is an alphanumeric text string used as an adjective that is intended to connote that the corresponding cell region is a clock buffer cell region. for which the driving strength of the cell region is DX, where X is a multiple of the unit driving strength D. FNCR 304(3) has x=32 such that the driving strength is D32.

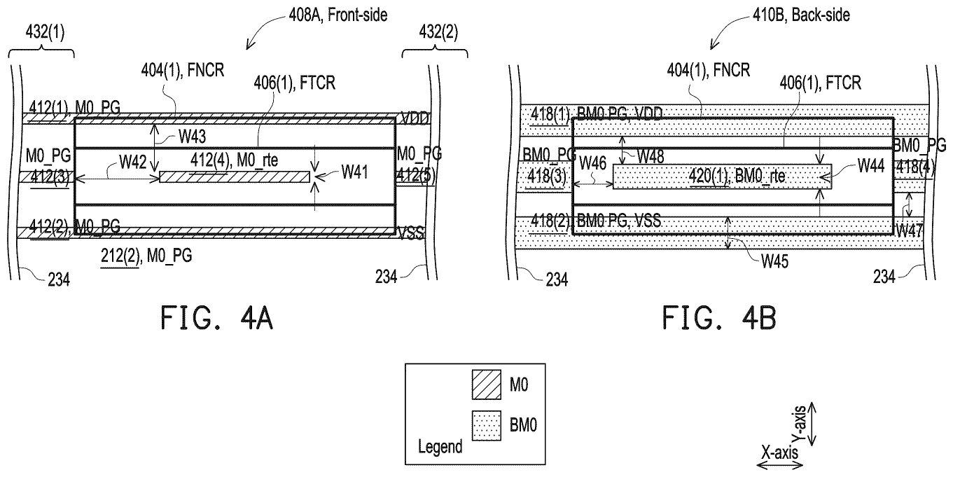

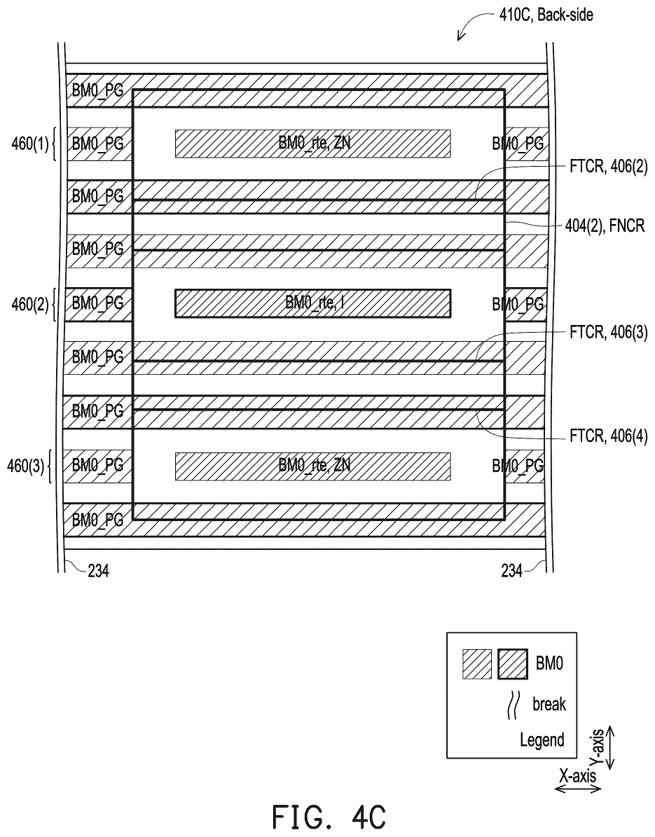

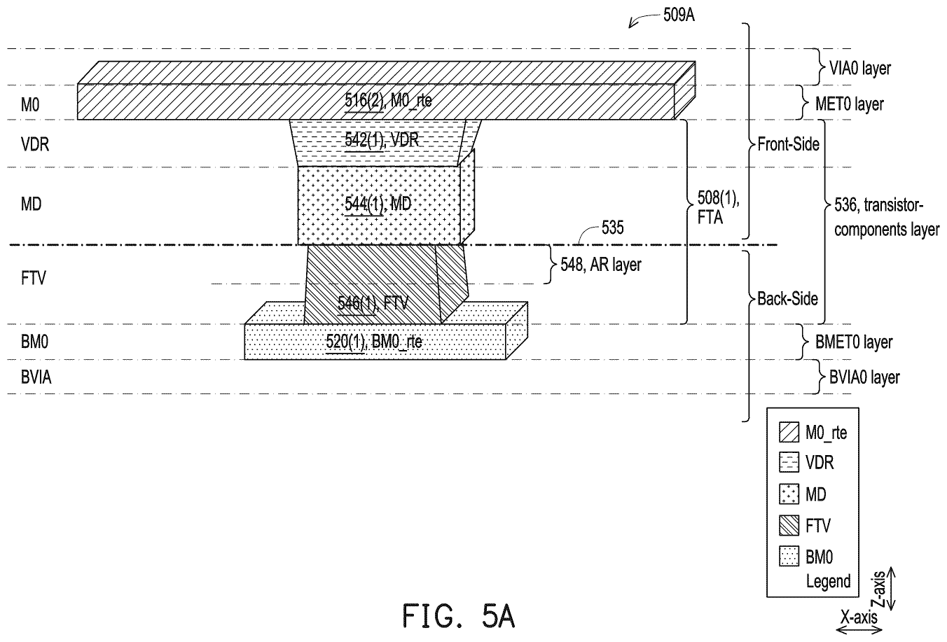

FIGS. 4A-4B are corresponding front-side 408A and back-side 410B layout diagrams of a functional circuit region 404(1), in accordance with some embodiments.

Front-side 408A and back-side 410B layout diagrams are similar correspondingly to front-side layout diagram 208A of FIG. 2A and back-side layout diagram 310B of FIG. 3B. For brevity, the discussion will focus on differences of front-side 408A and back-side 410B layout diagrams as compared to front-side layout diagram 208A of FIG. 2A and back-side layout diagram 310B of FIG. 3B rather than on similarities.

In FIG. 4A, the M0 segments extend parallel to the X-axis and include M0_PG segments 212(1)-212(2). Relative to the Y-axis: a top boundary correspondingly of each of FNCR 404(1) and FTCR 406(1) aligns substantially with a centerline of M0_PG segment 412(1); and a bottom boundary correspondingly of each of FNCR 404(1) and FTCR 406(1) aligns substantially with a centerline of M0_PG segment 412(2); and M0_PG segments 412(3)-414(5) are collinear.

Relative to the X-axis: M0_PG segment 412(4) is between M0_PG segments 416(3) and 414(5); M0_PG segment 412(4) is separated from M0_PG segment 412(3) by a first gap corresponding to a left boundary of FTCR 406(1); and M0_PG segment 412(4) is separated from M0_PG segment 412(5) by a second gap corresponding to a right boundary of FTCR 406(1).

Relative to the Y-axis: each of M0_PG segments 412(1)-412(5) has a width W41; each of the first and second gaps has a width W42; and adjacent ones of M0_PG segments 412(1)-412(5) are separated from each other by a third gap having a width W43.

Each of widths W41-W43 is determined according to the scale and corresponding ones of the design rules of the associated semiconductor process technology node. In some embodiments, one or both of the first and second gaps has/have a width different than W42.

In FIG. 4B, the BMO segments extend parallel to the X-axis and include BM0_PG segments 212(1)-212(2).

Relative to the Y-axis: a top boundary correspondingly of each of FNCR 404(1) and FTCR 406(1) aligns substantially with a centerline of BM0_PG segment 418(1); and a bottom boundary correspondingly of each of FNCR 404(1) and FTCR 406(1) aligns substantially with a centerline of BM0_PG segment 418(2); and BM0_PG segments 418(3)-414(4) and BM0_rte segment 420(1) are collinear.

Relative to the X-axis: BM0_rte segment 420(1) is between BM0_PG segments 418(3) and 418(4); BM0_rte segment 420(1) is separated from BM0_PG segment 418(3) by a fourth gap corresponding to a left boundary of FTCR 406(1); and BM0_rte segment 420(1)is separated from BM0_PG segment 418(5) by a fifth gap corresponding to a right boundary of FTCR 406(1). In some embodiments, taken together, BM0_PG segments 418(3) and 418(4) and BM0_rte segment 420(1) represent a first instance of a pieced-apart BMO segment.

Relative to the Y-axis: BM0_rte segment 420(1) has a width W44; each of BM0_PG segments 418(1)-418(4) has a width W45; each of the fourth and fifth gaps has a width W46; adjacent ones of BM0_PG segments 418(1)-418(4) are separated from each other by a sixth gap having a width W47; and BM0_rte segment 420(1) is separated from each of BM0_PG segments 418(1)-418(2) by a seventh gap having a width W48.

Each of widths W41-W48 is determined according to the scale and corresponding ones of the design rules of the associated semiconductor process technology node. In some embodiments, one or both of the fourth and fifth has/have a width different than W42. In FIG. 4B, width W44 is less than width W45 such that W44<W45. In FIGS. 4A-4B, width W41 is less than width W44 such that W41<W44. Each of BM0_PG segments 418(1)-418(2) is not notched, i.e., is notch-free, whereas corresponding BM0_PG segments 318(1)-318(2) of FIG. 3B are notched. Relative to the Y-axis, FNCR 404(1) has a height, h_404(1), as follows: h_404(1)=W44+2*W48+2*(W45/2).

According to another approach, a counterpart to FNCR 404(1) does not include routing segments in any metallization layer on the back-side, i.e., no routing segments in metallization layer BMET0 nor in any metallization therebelow. Rather, the other approach's (OO's) counterpart to FNCR 404(1) uses back-side metallization layers only for the power grid. In terms of signal routing, the OO's counterpart to FNCR 404(1) suffers congestion in the front-side metallization layers. By contrast, according to some embodiments, embedding a feedthrough cell region (e.g., FTCR 406(1) in a functional circuit region (e.g., FNCR 404(1)) facilitates using back-side metallization layers for signal routing as well as for the power grid, which reduces signal-routing congestion on the front-side as compared to the other approach.

FIG. 4C is back-side layout diagram 410C of a functional circuit region 304(1), in accordance with some embodiments.

Back-side layout diagram 410C is similar to back-side 410B of FIG. 4B. For brevity, the discussion will focus on differences of back-side 410C as compared to back-side layout diagram 410B of FIG. 4B rather than on similarities. FNCR 404(2) of FIG. 4C is an expanded version of FNCR 404(1) of FIG. 4B.

In FIG. 4C, FNCR 404(2) includes three M0_rte segments corresponding to a first pieced-apart BM0 segment 460(1), a second pieced-apart BM0 segment 460(2) and a third pieced-apart BMO segment 460(3). Relative to the Y-axis, FNCR 404(2) has a height, h_404(2), equal to four times the height of FNCR 404(1) of FIG. 4C such that h_404(2)=4*h_404(1).

FIG. 5B is a cross-section 509B of a device, in accordance with some embodiments.

More particularly, cross-section 509B is a cross-section of third and fourth FTCRs in corresponding third and fourth FNCRs, where the third and fourth FNCRs comprise a third macro cell region, and where the third macro cell region comprises a third device. In some embodiments, the third and fourth FTCRs are examples correspondingly of FTCR 206(4) and FTCR 206(5) of FIG. 2I, the third and fourth FNCRs are examples correspondingly of FNCR 204(4) and FNCR 204(5) of FIG. 2I, the third macro cell region is an example of macro cell region 202(1) of FIG. 2I, and the third device is an example of device 100 of FIG. 1. That is, in some embodiments, cross-section 509B corresponds to offset section line 5B-5B′ of FIG. 2I.

Cross-section 509B of FIG. 5B is similar to cross-section 509A of FIG. 5A. For brevity, the discussion will focus on differences of cross-section 509A of FIG. 5B as compared to cross-section 509A of FIG. 5A rather than on similarities.

As compared to cross-section 509A of FIG. 5A, cross-section 509B of FIG. 5B additionally includes structures correspondingly in layers BMET1, BVIA1, BMET2, MET1, VIA1 and MET2. Cross-section 509B includes FTA 508(2) and 508(3) which correspond to the first FTA and the second FTA of FIG. 2I. Cross-section 509B represents a signal path comprised of fragments F51-F57 that corresponding to signal path fragments F21-F27 of FIG. 2I.

FIGS. 6A-6D are block diagrams of corresponding macro cell regions 602A-602D, in accordance with some embodiments.

In FIG. 6A, macro cell region 602A includes an FNCR 604(1) and an FNCR 604(2). FNCR 604(1) has a front-side input and a back-side output. FNCR 604(2) has a back-side input and a front-side output. The back-side output of FNCR 604(1) is coupled to the back-side input of FNCR 604(2). In some embodiments, FNCR 604(1) and FNCR 604(2) represent corresponding buffers, drivers, or the like.

FNCR 604(1) includes an FTCR 606(1). A signal path between the front-side input and the back-side output of FNCR 604(1) includes FTCR 606(1). FNCR 604(2) includes an FTCR 606(2). A signal path between the back-side input and the front-side output of FNCR 604(2) includes FTCR 606(2).

In FIG. 6B, macro cell region 602B includes an FNCR 604(3) and an FNCR 604(4). FNCR 604(3) has a back-side input and a back-side output. FNCR 604(4) has a back-side input and a back-side output. The back-side output of FNCR 604(3) is coupled to the back-side input of FNCR 604(4). In some embodiments, FNCR 604(1) and FNCR 604(2) represent corresponding buffers, drivers, or the like.

FNCR 604(3) includes an FTCR 606(3) and an FTCR 606(4). A signal path between the back-side input and the back-side output of FNCR 604(3) includes FTCR 606(3) and FTCR 606(4).

Regarding FIG. 6C, macro cell region 606C is similar to macro cell region 606A of FIG. 6A. For brevity, the discussion will focus on differences of macro cell region 606C as compared to macro cell region 606A of FIG. 6A rather than on similarities.

In FIG. 6C, macro cell region 602C includes FNCR 604(2) of FIG. 6A and an FNCR 604(5). FNCR 604(5) has a front-side input and a back-side output. The back-side output of FNCR 604(5) is coupled to the back-side input of FNCR 604(2). In some embodiments, FNCR 604(5) represents a buffer, driver, or the like.

FNCR 604(5) includes an FTCR 606(7), an FTCR 606(8) and an FTCR 606(9). A signal path between the front-side input and the back-side output of FNCR 604(5) includes one or more of FTCR 606(7), FTCR 606(8) or FTCR 606(9).

In FIG. 6D, macro cell region 602D includes FNCR 604(3) of FIG. 6B, an FNCR 604(7) and an FNCR 604(8). In some embodiments, macro cell region 602D replaces FNCR 604(3) with FNCR 604(4) of FIG. 6B. FNCR 604(7) has a front-side input and a back-side output. FNCR 604(8) has a back-side input and a front-side output.

The back-side output of FNCR 604(7) is coupled to the back-side input of FNCR 604(3). The back-side output of FNCR 604(3) is coupled to the back-side input of FNCR 604(8). In some embodiments, FNCR 604(7) and FNCR 604(8) represent corresponding buffers, drivers, or the like.

FNCR 604(7) includes an FTCR 606(11). A signal path between the front-side input and the back-side output of FNCR 604(7) includes FTCR 606(11).

FNCR 604(8) includes an FTCR 606(12). A signal path between the back-side input and the front-side output of FNCR 604(8) includes FTCR 606(12).

FIG. 6E is a tree diagram of a device 600E, in accordance with some embodiments.

In some embodiments, device 600 is an example of device 100 of FIG. 1. The tree diagram of FIG. 6E is an example of H-tree architecture used for clock tree synthesis.

Device 600 includes: a macro cell region 602E(1) that represents a clock port at the root of the tree; a macro cell region 602E(2) that represents a trunk driver; a macro cell region 602E(3) that represents tap drivers; and a macro cell region 602(4) that represents local subtree drivers.

Macro cell region 602E(1) includes one or more instances of an FNCR 650 that has an input on the front-side and an output on the back-side. An example of FNCR 650 is FNCR 604(1) of FIG. 6A, or the like. Macro cell region 602E(2) includes one or more instances of an FNCR 652 that has an input on the back-side and an output on the back-side. An example of FNCR 652 is FNCR 604(3) of FIG. 6B, or the like. Macro cell region 602E(3) includes one or more instances of an FNCR 654 that has an input on the back-side and an output on the front-side. An example of FNCR 654 is FNCR 604(2) of FIG. 6A, or the like. Macro cell region 602E(4) includes: one or more instances of an FNCR 656 that has an input on the back-side and an output on the front-side; an integrated clock gating (ICG) cell region; and one or more instances of sink cell regions that represent leaves of the tree.

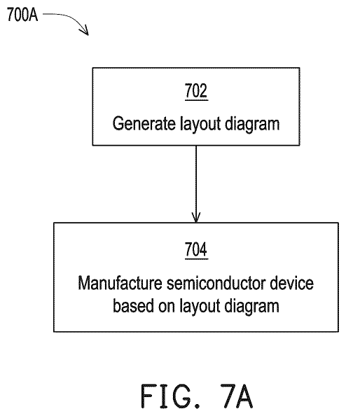

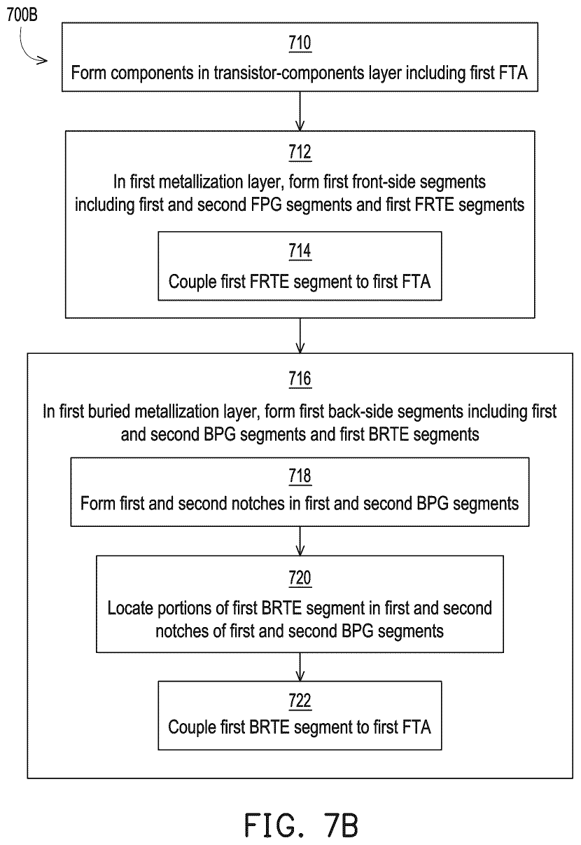

FIG. 7A is a flowchart (flow diagram) of a method 700A of manufacturing a system or device, in accordance with some embodiments.

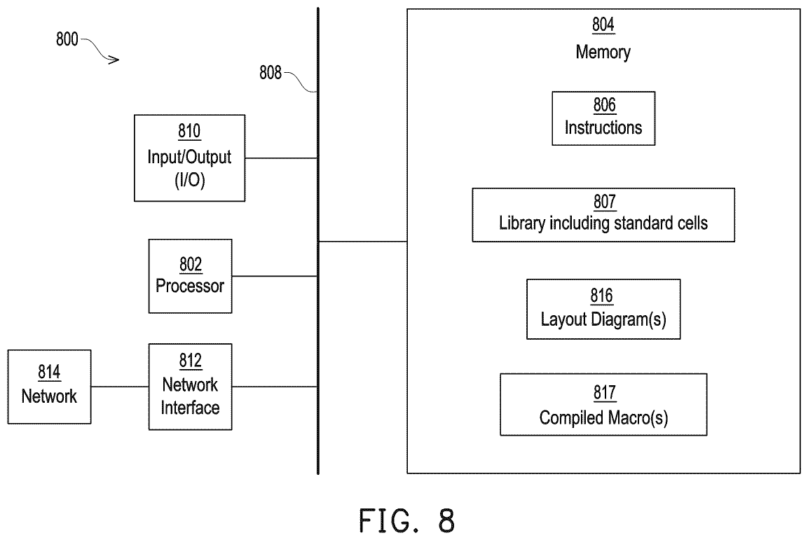

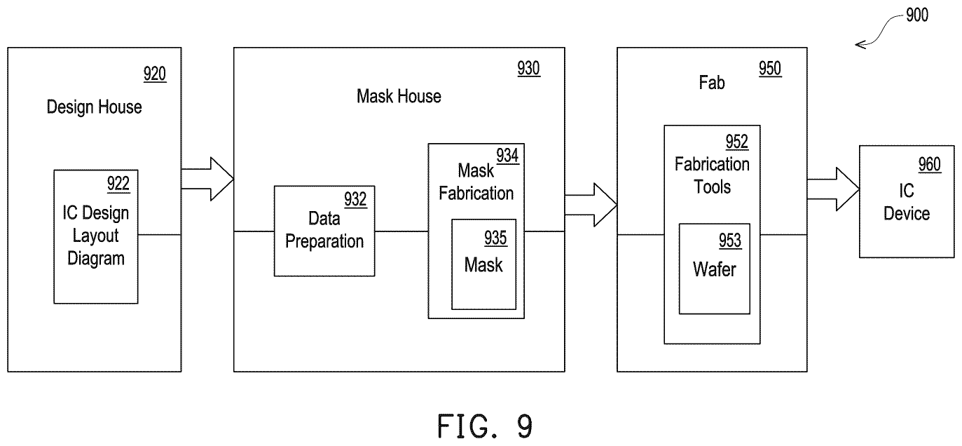

Method 700A is implementable, for example, using EDA system 800 (FIG. 8, discussed below) and an IC manufacturing system 900 (FIG. 9, discussed below), in accordance with some embodiments. Examples of an FNCR embedded with an FTCR which can be manufactured according to method 700A include the FTCR-embedded FNCRs disclosed herein, or the like.

In FIG. 7, the method of flowchart 700A includes blocks 702-704. At block 702, a layout diagram is generated which, among other things, includes one or more layout diagrams corresponding to one or more of the FTCR-embedded FNCRs disclosed herein, or the like. Block 702 is implementable, for example, using EDA system 800 (FIG. 8, discussed below), in accordance with some embodiments. From block 702, flow proceeds to block 704.

At block 704, based on the layout diagram, at least one of (A) one or more photolithographic exposures are made or (b) one or more photolithography masks are fabricated or (C) one or more components in a layer of a device, e.g., a device is fabricated. See discussion below of IC manufacturing system 900 in FIG. 9 below.

FIG. 7B is a flowchart 700B of a method of manufacturing a device, in accordance with some embodiments.

Flowchart 700B is an example of block 704 (see FIG. 7A, discussed above). The method of flowchart 700B is implementable, for example, using IC manufacturing system 900 (see FIG. 9, discussed below), in accordance with some embodiments. Examples of a devices which can be manufactured according to the method of flowchart 700B include devices that include the FTCR-embedded FNCRs disclosed herein, or the like. Flowchart 700B includes blocks 710-722.

At block 710, components are formed in a transistor layer (e.g., 536) including a first FTA (e.g., 508(1) or 508(2)). In some embodiments, block 710 includes forming a second FTA (e.g., 508(3)).

From block 710, flow proceeds to block 712.

At block 712, in a first metallization layer (e.g., MET0), first front-side segments are formed including first (e.g., 212(1)) and second (e.g., 212(2)) front-side power grid (FPG) segments and a front-side routing (FRTE) segment (e.g., 216(2), 516(2)). Inside block 712, flow proceeds into block 714.

At block 714, the first FRTE segment (e.g., 216(2), 516(2)) is coupled to the FTA (e.g., 508(1)). From block 714, flow exits block 712 and proceeds to block 716.

At block 716, in a first buried metallization layer (e.g., BMET0), first back-side segments are formed including first (e.g., 218(1)) and second (e.g., 218(2)) back-side power grid (BPG) segments and a first back-side routing (BRTE) segment (e.g., 220(1), 520(1)). From block 718, flow proceeds to block 720.

At block 720, portions of the first BRTE segment (e.g., 220(1), 520(1)) are located in first (e.g., 222(1)) and second (e.g., 222(2)) notches correspondingly of the first (e.g., 218(1)) and second (e.g., 218(2)) BPG segments. From block 720, flow proceeds to block 722.

At block 722, the first BRTE segment (e.g., 220(1), 520(1)) is coupled to the FTA (e.g., 508(1)). From block 722, flow exits block 716.

FIG. 8 is a block diagram of an electronic design automation (EDA) system 800 in accordance with some embodiments.

In some embodiments, EDA system 800 includes an automatic placement and routing (APR) system. In some embodiments, EDA system 800 is a general purpose computing device including a hardware processor 802 and a non-transitory, computer-readable storage medium 804. Storage medium 804, amongst other things, is encoded with, i.e., stores, computer program code 806, i.e., a set of executable instructions. Execution of instructions 806 by hardware processor 802 represents (at least in part) an EDA tool which implements a portion of or all, e.g., one or more methods of generating layout diagrams corresponding to the layout diagrams disclosed herein, or the like, in accordance with one or more embodiments (hereinafter, the noted processes and/or methods).

Storage medium 804, amongst other things, stores layout diagrams 811 such as the layout diagrams disclosed herein, other the like.

Processor 802 is electrically coupled to computer-readable storage medium 804 via a bus 808. Processor 802 is further electrically coupled to an I/O interface 810 by a bus 808. A network interface 812 is further electrically connected to processor 802 via bus 808. Network interface 812 is connected to a network 814, so that processor 802 and computer-readable storage medium 804 are capable of connecting to external elements via network 814. Processor 802 is configured to execute computer program code 806 encoded in computer-readable storage medium 804 in order to cause EDA system 800 to be usable for performing a portion of or all the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, computer-readable storage medium 804 is an electronic, magnetic, optical, electromagnetic, infrared, and/or a semiconductor system (or apparatus or device). For example, computer-readable storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 804 includes a compact disk-read only memory (CD-ROM), a compact disk-read/write (CD-R/W), and/or a digital video disc (DVD).

In one or more embodiments, storage medium 804 stores computer program code 806 configured to cause EDA system 800 (where such execution represents (at least in part) the EDA tool) to be usable for performing a portion of or all the noted processes and/or methods. In one or more embodiments, storage medium 804 further stores information which facilitates performing a portion of or all the noted processes and/or methods. In one or more embodiments, storage medium 804 stores library 807 of standard cells including standard cells that correspond to components of the layout diagrams disclosed herein. Storage medium 804 stores one or more layout diagrams 816 such as one or more layout diagrams corresponding to the layout diagrams disclosed herein, or the like.

EDA system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

EDA system 800 further includes network interface 812 coupled to processor 802. Network interface 812 allows EDA system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion of or all noted processes and/or methods, is implemented in two or more EDA systems 800.

EDA system 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. EDA system 800 is configured to receive information related to a user interface (UI) through I/O interface 810. The information is stored in computer-readable medium 804 as UI 842.

In some embodiments, a portion of or all the noted processes and/or methods is implemented as a standalone software application for execution by a processor. In some embodiments, a portion of or all the noted processes and/or methods is implemented as a software application that is a part of an additional software application. In some embodiments, a portion of or all the noted processes and/or methods is implemented as a plug-in to a software application. In some embodiments, at least one of the noted processes and/or methods is implemented as a software application that is a portion of an EDA tool. In some embodiments, a portion of or all the noted processes and/or methods is implemented as a software application that is used by EDA system 800. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 9 is a block diagram of an integrated circuit (IC) manufacturing system 900, and an IC manufacturing flow associated therewith, in accordance with some embodiments.

In some embodiments, based on the layout diagram generated by block 702 of FIG. 7, the IC manufacturing system 900 implements block 704 of FIG. 7 wherein at least one of (A) one or more semiconductor masks or (B) at least one component in a layer of an inchoate semiconductor integrated circuit is fabricated using manufacturing system 900. In some embodiments, the IC manufacturing system 900 implements the flowcharts of FIG. 5, or the like.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout 922. IC design layout 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout 922 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 920 implements a proper design procedure to form IC design layout 922. The design procedure includes one or more of logic design, physical design or place and route. IC design layout 922 is presented in one or more data files having information of the geometrical patterns. For example, IC design layout 922 is expressed in a GDSII file format or DFII file format.

Mask house 930 includes data preparation 932 and mask fabrication 934. Mask house 930 uses IC design layout 922 to manufacture one or more masks 935 to be used for fabricating the various layers of IC device 960 according to IC design layout 922. Mask house 930 performs mask data preparation 932, where IC design layout 922 is translated into a representative data file (“RDF”). Mask data preparation 932 supplies the RDF to mask fabrication 934. Mask fabrication 934 includes a mask writer. A mask writer converts the RDF to an image on a substrate, such as a mask (reticle) or a semiconductor wafer. The design layout is manipulated by mask data preparation 932 to comply with particular characteristics of the mask writer and/or requirements of IC fab 950. In FIG. 9, mask data preparation 932, mask fabrication 934, and mask 935 are illustrated as separate elements. In some embodiments, mask data preparation 932 and mask fabrication 934 are collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout 922. In some embodiments, mask data preparation 932 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 934, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout 922 to fabricate a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are repeated to further refine IC design layout 922.

The above description of mask data preparation 932 has been simplified for the purposes of clarity. In some embodiments, mask data preparation 932 includes additional features such as a logic operation (LOP) to modify the IC design layout according to manufacturing rules. Additionally, the processes applied to IC design layout 922 during data preparation 932 may be executed in a variety of different orders.

After mask data preparation 932 and during mask fabrication 934, a mask 935 or a group of masks 935 are fabricated based on the modified IC design layout. In some embodiments, an electron-beam (e-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

IC fab 950 is an IC fabrication business that includes one or more manufacturing facilities for the fabrication of a variety of different IC products. In some embodiments, IC fab 950 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 950 uses mask (or masks) 935 fabricated by mask house 930 to fabricate IC device 960 using fabrication tools 952. Thus, IC fab 950 at least indirectly uses IC design layout 922 to fabricate IC device 960. In some embodiments, a semiconductor wafer 953 is fabricated by IC fab 950 using mask (or masks) 935 to form IC device 960. Semiconductor wafer 953 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a cell region includes: a transistor-components layer including a first feedthrough via arrangement (FTA); a first metallization layer over the transistor-components layer and including first-front-side segments extending in a first direction (e.g., parallel to the X-axis), the first front-side segments including first and second front-side power grid (FPG) segments, and one or more front-side routing (FRTE) segments including a first FRTE segment; and a first buried metallization layer under the transistor-components layer and including first back-side segments extending in the first direction, the first back-side segments including first and second back-side power grid (BPG) segments, and one or more back-side routing (BRTE) segments including a first BRTE segment. The first FTA couples the first FRTE segment to the first BRTE segment. Relative to the first direction and a second direction perpendicular to the first direction, the first BPG segment having a first notch partially occupied by at least a first portion of the first BRTE segment.

In some embodiments, relative to the second direction, the first BRTE segment is between the first and second BPG segments; and the second BPG segment has a second notch partially occupied by at least a second portion of the first BRTE segment.

In some embodiments, top and bottom boundaries of the cell region extend in the first direction; each of the first FPG segment and the first BPG segment correspondingly overlaps the top boundary; and each of the second FPG segment and the second BPG segment correspondingly overlaps the bottom boundary.

In some embodiments, top and bottom boundaries of the cell region extend in the first direction; the first back-side segments further include a third BPG segment; the second BPG segment is between the first BPG segment and the third BPG segment relative to the second direction; each of the first FPG segment and the first BPG segment correspondingly overlaps the top boundary; and each of the second FPG segment and the third BPG segment correspondingly overlaps the bottom boundary.

In some embodiments, the cell region further includes a first buried interconnection layer under the transistor-components layer and including first back-side vias, and wherein: the first back-side vias correspondingly overlap the first back-side segments; ones of the first back-side vias that are proximal to the first notch are proximal BVs; each of the proximal BVs is separated from the first notch by a corresponding first BV-offset distance relative to the first direction or a corresponding second BV-offset distance relative to the second direction; each first BV-offset distance is equal to or greater than a first reference distance; and each second BV-offset distance is equal to or greater than a second reference distance.

In some embodiments, regarding a centerline that extends in the first direction through the first BPG segment, and further regarding centerlines that extend correspondingly in the first direction through the first back-side vias including the proximal BVs, and relative to the second direction, the centerlines correspondingly of one or more selected ones of the proximal BVs are displaced from the centerline of the first BPG segment.

In some embodiments, regarding a centerline that extends in the first direction through the second BPG segment, and except for the one or more selected ones of the proximal BVs, and relative to the second direction, the centerlines correspondingly of the first back-side vias are substantially collinear with the centerline correspondingly of the first BPG segment or the second BPG segment.

In some embodiments, the cell region represents a functional circuit; that includes an input pin and configured to receive an input signal and an output pin configured to provide an output signal; the input pin is on an opposite one of the front-side or the back-side of the cell region as compared to the output pin; and a signal path coupling the input pin to the output pin; includes the first FTA.

In some embodiments, the transistor-components layer further includes a second FTA; the cell region represents a functional circuit; that includes an input pin and configured to receive an input signal and an output pin configured to provide an output signal; the input pin is on a same one of the front-side or the back-side of the cell region as compared to the output pin; and a signal path coupling the input pin to the output pin; includes the first FTA and the second FTA.

In some embodiments, relative to the second direction, and excluding a portion of the first BPG segment having a first notch, a width of the first BRTE segment is less than a width of each of the first BPG segment and the second BPG segment.

In some embodiments, relative to the second direction, and a width of the first BRTE segment is greater than a width of each of the first FPG segment and the second FPG segment.

In some embodiments, a cell region includes: a transistor-components layer including a first feedthrough via arrangement (FTA); a first metallization layer over the transistor-components layer and including first-front-side segments extending in a first direction, the first front-side segments including:
first and second front-side power grid (FPG) segments; and one or more front-side routing (FRTE) segments including a first FRTE segment; and a first buried metallization layer under the transistor-components layer and including first back-side segments extending in the first direction, the first back-side segments including: first, second and third back-side power grid (BPG) segments; and one or more back-side routing (BRTE) segments including a first BRTE segment; the first FTA coupling the first FRTE segment to the first BRTE segment; and the second and third BPG segments and the first FRTE segment being substantially collinear; and the first BRTE segment being between the second and third BPG segments.

In some embodiments, the first-front-side segments further include third and fourth FPG segments; the third and fourth BPG segments are between the first BPG segment and the second BPG segment; the third and fourth FPG segments and the first RTE segment are substantially collinear; and the first RTE segment is between the third and fourth FPG segments.

In some embodiments, the first back-side segments further include a fourth BPG segment; the second and third BPG segments are between the first BPG segment and the fourth BPG segment relative to a second direction perpendicular to the first direction; each of the first FPG segment and the first BPG segment correspondingly overlaps a top boundary of the cell region; and each of the second FPG segment and the fourth BPG segment BPG segment correspondingly overlaps a bottom boundary of the cell region.

In some embodiments, relative to a second direction perpendicular to the first direction, and a width of the first BRTE segment is less than a width of each of the first, second, third and fourth BPG segments.

In some embodiments, relative to a second direction perpendicular to the first direction, and a width of the first BRTE segment is greater than a width of each of the first and second FPG segments.

In some embodiments, a method (of manufacturing a cell region) includes:
forming components in a transistor-components layer including a first feedthrough via arrangement (FTA); in a first metallization layer over the transistor-components layer, forming first front-side segments extending in a first direction and including first and second front-side power grid (FPG) segments, and one or more front-side routing (FRTE) segments including a first FRTE segment; and in a first buried metallization layer under the transistor-components layer, forming first back-side segments extending in the first direction and including first and second back-side power grid (BPG) segments, and one or more back-side routing (BRTE) segments including a first BRTE segment; the forming first front-side segments including coupling the first FRTE segment to the first FTA; and the forming first back-side segments including: relative to the first direction and a second direction perpendicular to the first direction, forming a first notch in the first BPG segment; and locating the first BRTE segment so that at least a first portion of the first BRTE segment partially occupies the first notch; and coupling the first BRTE segment to the first FTA.

In some embodiments, the forming first back-side segments further includes, relative to the second direction, locating the first BRTE segment between the first and second BPG segments; relative to the first direction and the second direction, forming a second notch in the second BPG segment; and locating the first BRTE segment so that at least a second portion of the first BRTE segment partially occupies the second notch.

In some embodiments, the method further includes, in a first buried interconnection layer under the first buried metallization layer, forming first back-side vias, and wherein: the forming first back-side vias includes locating the first back-side vias to overlap correspondingly the first back-side segments, and ones of the first back-side vias that are proximal to the first notch are proximal BVs; the forming first back-side vias further includes separating each of the proximal BVs from the first notch by a corresponding first BV-offset distance relative to the first direction or a corresponding second BV-offset distance relative to the second direction; each first BV-offset distance is equal to or greater than a first reference distance; and each second BV-offset distance is equal to or greater than a second reference distance.

In some embodiments, regarding a centerline that extends in the first direction through the first BPG segment, and further regarding centerlines that extend correspondingly in the first direction through the first back-side vias including the proximal BVs, and relative to the second direction, the forming first back-side vias further includes: displacing the centerlines correspondingly of one or more selected ones of the proximal BVs from the centerline of the first BPG segment.

In some embodiments, regarding a centerline that extends in the first direction through the second BPG segment, and, except for the one or more selected ones of the proximal BVs, and relative to the second direction, the forming first back-side vias further includes substantially collinearly aligning the centerlines correspondingly of the first back-side vias with the centerline correspondingly of the first BPG segment or the second BPG segment.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

1. A cell region comprising:
a transistor-components layer including a first feedthrough via arrangement (FTA);
a first metallization layer over the transistor-components layer and including first-front-side segments extending in a first direction, the first front-side segments including:
first and second front-side power grid (FPG) segments; and
one or more front-side routing (FRTE) segments including a first FRTE segment; and
a first buried metallization layer under the transistor-components layer and including first back-side segments extending in the first direction, the first back-side segments including:
first and second back-side power grid (BPG) segments; and
one or more back-side routing (BRTE) segments including a first BRTE segment;
the first FTA coupling the first FRTE segment to the first BRTE segment; and
relative to the first direction and a second direction perpendicular to the first direction, the first BPG segment having a first notch partially occupied by at least a first portion of the first BRTE segment.

2. The cell region of claim 1, wherein:
relative to the second direction, the first BRTE segment is between the first and second BPG segments; and
the second BPG segment has a second notch partially occupied by at least a second portion of the first BRTE segment.

3. The cell region of claim 2, wherein:
top and bottom boundaries of the cell region extend in the first direction;
each of the first FPG segment and the first BPG segment correspondingly overlaps the top boundary; and
each of the second FPG segment and the second BPG segment correspondingly overlaps the bottom boundary.

4. The cell region of claim 2, wherein:
top and bottom boundaries of the cell region extend in the first direction;
the first back-side segments further include:
a third BPG segment;
the second BPG segment is between the first BPG segment and the third BPG segment relative to the second direction;
each of the first FPG segment and the first BPG segment correspondingly overlaps the top boundary; and
each of the second FPG segment and the third BPG segment correspondingly overlaps the bottom boundary.

5. The cell region of claim 1, further comprising:
a first buried interconnection layer under the transistor-components layer and including first back-side vias; and
wherein:
the first back-side vias correspondingly overlap the first back-side segments;
ones of the first back-side vias that are proximal to the first notch are proximal BVs;
each of the proximal BVs is separated from the first notch by a corresponding first BV-offset distance relative to the first direction or a corresponding second BV-offset distance relative to the second direction;
each first BV-offset distance is equal to or greater than a first reference distance; and
each second BV-offset distance is equal to or greater than a second reference distance.

6. The cell region of claim 5, wherein:
regarding a centerline that extends in the first direction through the first BPG segment, and
further regarding centerlines that extend correspondingly in the first direction through the first back-side vias including the proximal BVs, and
relative to the second direction,
the centerlines correspondingly of one or more selected ones of the proximal BVs are displaced from the centerline of the first BPG segment.

7. The cell region of claim 6, wherein:
regarding a centerline that extends in the first direction through the second BPG segment, and
except for the one or more selected ones of the proximal BVs, and
relative to the second direction,
the centerlines correspondingly of the first back-side vias are substantially collinear with the centerline correspondingly of the first BPG segment or the second BPG segment.

8. The cell region of claim 1, wherein:
the cell region represents a functional circuit; that includes an input pin and configured to receive an input signal and an output pin configured to provide an output signal;
the input pin is on an opposite one of the front-side or the back-side of the cell region as compared to the output pin; and
a signal path coupling the input pin to the output pin; includes the first FTA.

9. The cell region of claim 1, wherein:
the transistor-components layer further includes a second FTA;
the cell region represents a functional circuit; that includes an input pin and configured to receive an input signal and an output pin configured to provide an output signal;
the input pin is on a same one of the front-side or the back-side of the cell region as compared to the output pin; and
a signal path coupling the input pin to the output pin; includes the first FTA and the second FTA.

10. The cell region of claim 1, wherein:
relative to the second direction, and
excluding a portion of the first BPG segment having a first notch,
a width of the first BRTE segment is less than a width of each of the first BPG segment and the second BPG segment.

11. The cell region of claim 11, wherein:
relative to the second direction, and
a width of the first BRTE segment is greater than a width of each of the first FPG segment and the second FPG segment.

12. A cell region comprising:
a transistor-components layer including a first feedthrough via arrangement (FTA);
a first metallization layer over the transistor-components layer and including first-front-side segments extending in a first direction, the first front-side segments including:
first and second front-side power grid (FPG) segments; and
one or more front-side routing (FRTE) segments including a first FRTE segment; and
a first buried metallization layer under the transistor-components layer and including first back-side segments extending in the first direction, the first back-side segments including:
first, second and third back-side power grid (BPG) segments; and
one or more back-side routing (BRTE) segments including a first BRTE segment;
the first FTA coupling the first FRTE segment to the first BRTE segment; and
the second and third BPG segments and the first FRTE segment being substantially collinear; and
the first BRTE segment being between the second and third BPG segments.

13. The cell region of claim 12, wherein:
the first-front-side segments further include third and fourth FPG segments;
the third and fourth BPG segments are between the first BPG segment and the second BPG segment;
the third and fourth FPG segments and the first RTE segment are substantially collinear; and
the first RTE segment is between the third and fourth FPG segments.

14. The cell region of claim 13, wherein:
the first back-side segments further include:
a fourth BPG segment;
the second and third BPG segments are between the first BPG segment and the fourth BPG segment relative to a second direction perpendicular to the first direction;
each of the first FPG segment and the first BPG segment correspondingly overlaps a top boundary of the cell region; and
each of the second FPG segment and the fourth BPG segment BPG segment correspondingly overlaps a bottom boundary of the cell region.

15. The cell region of claim 13, wherein:
relative to a second direction perpendicular to the first direction, and
a width of the first BRTE segment is less than a width of each of the first, second, third and fourth BPG segments.

16. The cell region of claim 12, wherein:
relative to a second direction perpendicular to the first direction, and
a width of the first BRTE segment is greater than a width of each of the first and second FPG segments.

17. A method of manufacturing a cell region, the method comprising:
forming components in a transistor-components layer including a first feedthrough via arrangement (FTA);
in a first metallization layer over the transistor-components layer,
forming first front-side segments extending in a first direction and including:
first and second front-side power grid (FPG) segments; and
one or more front-side routing (FRTE) segments including a first FRTE segment; and
in a first buried metallization layer under the transistor-components layer,
forming first back-side segments extending in the first direction and including:
first and second back-side power grid (BPG) segments; and
one or more back-side routing (BRTE) segments including a first BRTE segment;
the forming first front-side segments including:
coupling the first FRTE segment to the first FTA; and
the forming first back-side segments including:
relative to the first direction and a second direction perpendicular to the first direction,
forming a first notch in the first BPG segment; and
locating the first BRTE segment so that at least a first portion of the first BRTE segment partially occupies the first notch; and
coupling the first BRTE segment to the first FTA.

18. The method of claim 17, wherein the forming first back-side segments further includes:
relative to the second direction,
locating the first BRTE segment between the first and second BPG segments;
relative to the first direction and the second direction,
forming a second notch in the second BPG segment; and
locating the first BRTE segment so that at least a second portion of the first BRTE segment partially occupies the second notch.

19. The method of claim 17, further comprising:
in a first buried interconnection layer under the first buried metallization layer,
forming first back-side vias; and
wherein:
the forming first back-side vias includes:
locating the first back-side vias to overlap correspondingly the first back-side segments; and
ones of the first back-side vias that are proximal to the first notch are proximal BVs;
the forming first back-side vias further includes:
separating each of the proximal BVs from the first notch by a corresponding first BV-offset distance relative to the first direction or a corresponding second BV-offset distance relative to the second direction;
each first BV-offset distance is equal to or greater than a first reference distance; and
each second BV-offset distance is equal to or greater than a second reference distance.

20. The method of claim 19, wherein:
regarding a centerline that extends in the first direction through the first BPG segment, and
further regarding centerlines that extend correspondingly in the first direction through the first back-side vias including the proximal BVs, and
relative to the second direction, the forming first back-side vias further includes:
displacing the centerlines correspondingly of one or more selected ones of the proximal BVs from the centerline of the first BPG segment.
